(19) United States
(12) Patent Application Publication
(10) Pub. No.: US 2010/0044815 A1
(43) Pub. Date: Feb. 25, 2010

(54) CMOS IMAGE SENSOR PACKAGE AND CAMERA MODULE USING SAME

(75) Inventor: Jen-Tsorng CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/467,295

(22) Filed: May 17, 2009

(30) Foreign Application Priority Data
Aug. 20, 2008 (CN) 200810304077.2

(51) Int. Cl. H01L 31/0232

(52) U.S. Cl. 257/432; 257/E31.127

(57) ABSTRACT

An image sensor package includes a cover glass, a color filter layer, an image sensor chip, and a reflecting layer. The cover glass includes a first surface and a second surface at opposite sides thereof. The color filter layer is formed on the first surface of the cover glass. The image sensor chip includes a silicon layer formed on the second surface of the cover glass, a number of pixel regions formed on a third surface of the silicon layer facing away from the cover glass, and a number of bumps formed on the third surface of the silicon layer, the bumps is capable of for electrically connecting the image sensor chip to a circuit board. The reflecting layer covers the pixel regions of the image sensor chip.

### CROSS-REFERENCE TO RELATED APPLICATION

This application is related to a copending U.S. patent application, Ser. No. [to be advised], filed under Attorney docket No. US21563 simultaneously with the present application, entitled “CMOS IMAGE SENSOR PACKAGE AND CAMERA MODULE WITH SAME,” and having the same assignee as the present application. The disclosure of the above-identified application is incorporated herein by reference.

### BACKGROUND

1. Technical Field

The present disclosure relates to solid state image sensors and, particularly, to a complementary metal oxide semiconductor (CMOS) image sensor package and a camera module using the CMOS image sensor package.

2. Description of Related Art

With the ongoing development of optical imaging technology, camera modules are becoming widely used in numerous electronic devices, such as digital cameras and mobile phones. Solid state color image sensors including semiconductor equipment such as charge-coupled devices (CCDs) and CMOS image sensors are widely used in these camera modules.

An image sensor is usually packed in an image sensor package prior to being assembled on a circuit board. A typical image sensor package includes a plastic or ceramic substrate with the image sensor mounted thereon, an enclosure mounted on the substrate and surrounding the image sensor, and a cover glass secured on the enclosure for protecting the image sensor from dust, etc. The image sensor package usually has a much bigger size than the image sensor itself, and adds to the bulk of the camera module.

What is needed, therefore, is an image sensor package with a relatively small size to overcome or at least alleviate the above-described problem.

### BRIEF DESCRIPTION OF THE DRAWINGS

Many aspects of the present CMOS image sensor package and camera module can be better understood with reference to the accompanying drawings. The components in the drawings are not necessarily drawn to scale, the emphasis instead being placed upon clearly illustrating the principles of the present CMOS image sensor package and camera module. In the drawings, all the views are schematic.

FIG. 1 is a cross-sectional view of a camera module according to a first exemplary embodiment.

FIG. 2 is an inverted view of an image sensor package of the camera module of FIG. 1.

FIG. 3 is a cross-sectional view of an image sensor package according to a second exemplary embodiment.

### DETAILED DESCRIPTION

Embodiments of the present disclosure will now be described in detail below, with reference to the accompanying drawings.

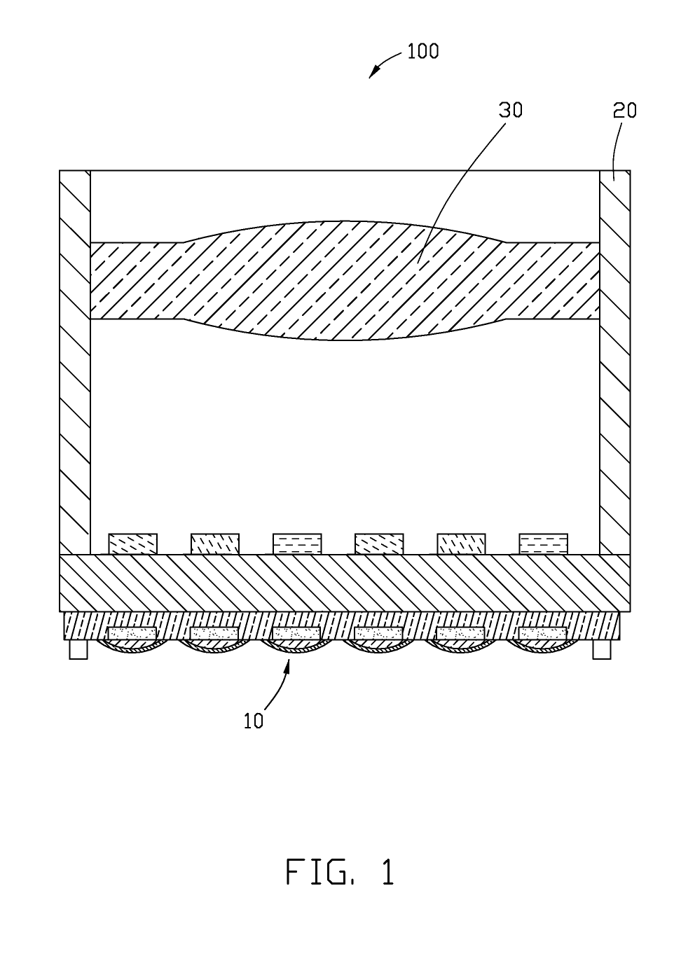

Referring to FIG. 1, a camera module 100, according to an exemplary embodiment, is shown. The camera module 100 includes an image sensor package 10, a barrel 20, and a lens 30 received in the barrel 20.

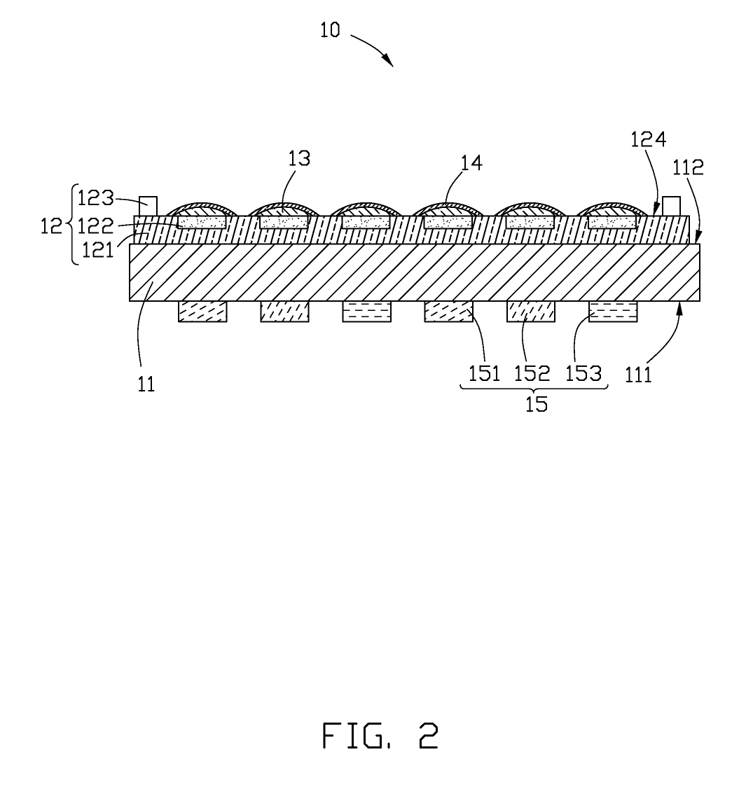

The image sensor package 10 is located at the image side of the lens 30. Further referring to FIG. 2, the image sensor package 10 includes a cover glass 11, an image sensor chip 12, a micro-lens array 13, a reflecting layer 14, and a color filter layer 15.

The cover glass 11 includes a first surface 111 and a second surface 112 at opposite sides thereof. The first surface 111 faces toward the object side of the camera module 100.

The image sensor chip 12 is formed on the second surface 112 of the cover glass 11. The image sensor chip 12 includes a silicon layer 121, a plurality of pixel regions 122, and a number of bumps 123.

The silicon layer 121 is attached to the second surface 112 of the cover glass 11. The thickness of the silicon layer 121 can be in a range from approximately 0.1 μm to approximately 100 μm. The silicon layer 121 includes a third surface 124 facing away from the cover glass 11. The pixel regions 122 and the bumps 123 are formed on the third surface 124 of the silicon layer 121. Because the silicon layer 121 is very thin, the silicon layer 121 is substantially transparent. The pixel regions 122 are configured for converting light beam incident thereon into electric signals. The bumps 123 are used for electrically connecting the image sensor chip 12 to a circuit board (not shown).

The micro-lens array 13 is mounted on the third surface 124 of the silicon layer 121. The micro-lens array 13 includes a number of micro lenses, wherein each micro lens covers a pixel region 122 of the image sensor chip 12. The micro-lens array 13 can focus light beams passing through the silicon layer 121 to the reflecting layer 14. The reflecting layer 14 is coated on the micro-lens array 13 for reflecting the light beam focused by the micro-lens array 13 toward the pixel regions 122. Thus, the light sensitivity of the image sensor chip 12 can be improved. Preferably, the diameter of each micro lens of the micro-lens array 13 is larger than the size of each pixel region 122. With such configuration, some light beams that pass through the silicon layer 121 without being incident on the pixel regions 122 can be focused and reflected back to the pixel regions 122. Accordingly, the light sensitivity of the image sensor chip 12 can be further improved. In addition, the micro-lens array 13 and the reflecting layer 14 covering the pixel regions 122 can protect the pixel regions 122 from dust, contaminants, etc. The reflecting layer 14 can be a metal layer or a reflective film. In the illustrated embodiment, the reflecting layer 14 is discontinuous. That is, the reflecting layer 14 includes a plurality of discrete portions covering the micro lenses, respectively.

The color filter layer 15 is formed on the first surface 111 of the cover glass 11. The color filter layer 15 includes three different kinds of color filters. In the present embodiment, the color filter layer 15 includes a number of red color filters 151, a number of green color filters 152, and a number of blue color filters 153.

In the present embodiment, a method of manufacturing the image sensor package 10 includes the following steps: providing the cover glass 11; depositing a silicon layer 121 on the second surface 112 of the cover glass 11; forming the pixel regions 122 and the bumps 123 on the third surface 124 of the silicon layer 121 to form an image sensor chip 12; covering the pixel regions 122 of the image sensor chip 12 with the micro-lens array 13; coating the reflecting layer 14 on the micro-lens array 13; and forming a color filter layer 15 on the first surface 111 of the cover glass 11.

In the present embodiment, the cover glass 11 is a heat-resistant glass capable of withstanding relatively high temperatures. Therefore, the silicon layer 121 can be deposited on the second surface 112 of the cover glass 11 directly. With the support of the cover glass 11, the thickness of the silicon layer 121 can be minimal. The micro-lens array 13 can be made of photoresist material. Therefore, the shapes of the micro lenses of the micro-lens array 13 can be conveniently controlled.

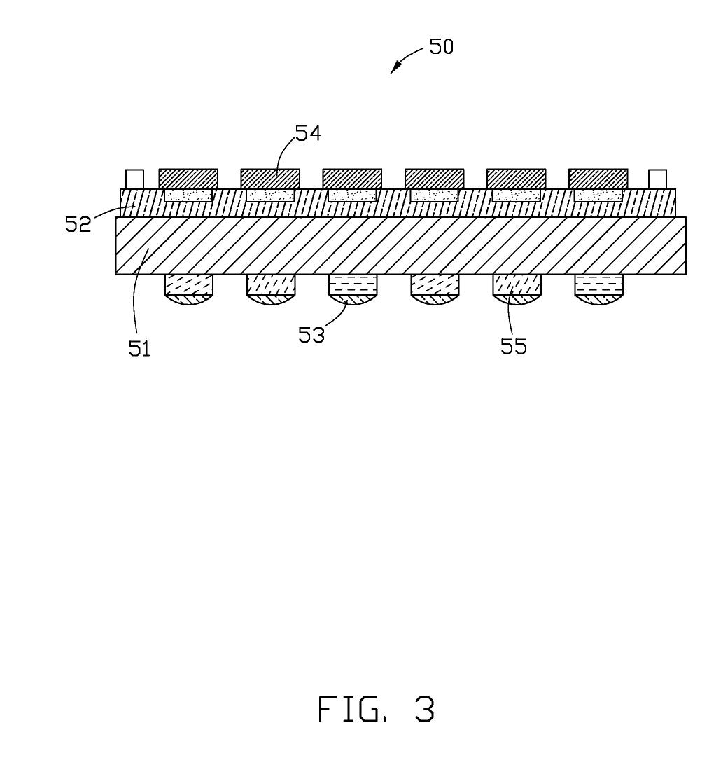

Referring to FIG. 3, an image sensor package 50, according to a second exemplary embodiment, is shown. The image sensor package 50 includes a cover glass 51, an image sensor chip 52, a micro-lens array 53, a reflecting layer 54, and a color filter layer 55. The image sensor package 50 is similar to the image sensor package 10 of the first exemplary embodiment. The difference between the image sensor package 50 and the image sensor package 10 is that the position of the micro-lens array 53 in the image sensor package 50 is different from that of the micro-lens array 13 in the image sensor package 10. The micro-lens array 53 overlays a surface of the color filter layer 55 that is farthest away from the cover glass 51.

While certain embodiments have been described and exemplified above, various other embodiments will be apparent to those skilled in the art from the foregoing disclosure. The invention is not limited to the particular embodiments described and exemplified, and the embodiments are capable of considerable variation and modification without departure from the scope and spirit of the appended claims.

What is claimed is:

1. An image sensor package comprising:
a cover glass comprising a first surface and a second surface at opposite sides thereof;
a color filter layer formed on the first surface of the cover glass;
an image sensor chip comprising:
a silicon layer formed on the second surface of the cover glass, the silicon layer comprising a third surface facing away from the cover glass;
a plurality of pixel regions formed on the third surface of the silicon layer; and
a plurality of bumps formed on the third surface of the silicon layer, the bumps capable of electrically connecting the image sensor chip to a circuit board, and
a reflecting layer covering the plurality of pixel regions of the image sensor chip.

2. The image sensor package of claim 1, wherein the cover glass is heat-resistant glass.

3. The image sensor package of claim 2, wherein the silicon layer is a deposition layer on the cover glass.

4. The image sensor package of claim 1, wherein the thickness of the silicon layer is in a range from approximately 0.1 μm to approximately 100 μm.

5. The image sensor package of claim 1, wherein the silicon layer is substantially transparent.

6. The image sensor package of claim 1, further comprising a micro-lens array arranged between the plurality of pixel regions and the reflecting layer, the micro-lens array comprising a plurality of micro lenses covering the plurality of pixel regions, respectively.

7. The image sensor package of claim 6, wherein the diameter of each micro lens is larger than the corresponding size of the respective pixel region.

8. The image sensor package of claim 6, wherein the micro-lens array is made of photoresist material.

9. The image sensor package of claim 1, further comprising a micro-lens array overlaying a surface of the color filter layer that is farthest away from the cover glass.

10. The image sensor package of claim 1, wherein the color filter layer comprises a plurality of red color filters, a plurality of green color filters, and a plurality of blue color filters.

11. A camera module comprising:
a barrel;
at least one lens received in the barrel; and
an image sensor package located at the image side of the at least one lens, the image sensor package comprising:
a cover glass comprising a first surface and a second surface at opposite sides thereof, the first surface facing toward the object side of the camera module;
a color filter layer formed on the first surface of the cover glass;
an image sensor chip comprising: a silicon layer formed on the second surface of the cover glass, the silicon layer comprising a third surface facing away from the cover glass; a plurality of pixel regions formed on the third surface of the silicon layer; and a plurality of bumps formed on the third surface of the silicon layer, the bumps capable of electrically connecting the image sensor chip to a circuit board, and
a reflecting layer covering the plurality of pixel regions of the image sensor chip.

12. The camera module of claim 11, wherein the cover glass is a heat-resistant glass.

13. The camera module of claim 12, wherein the silicon layer is a deposition layer on the cover glass.

14. The camera module of claim 11, wherein the thickness of the silicon layer is in a range from approximately 0.1 μm to approximately 100 μm.

15. The camera module of claim 11, wherein the silicon layer is substantially transparent.

16. The camera module of claim 11, further comprising a micro-lens array arranged between the plurality of pixel regions and the reflecting layer, the micro-lens array comprising a plurality of micro lenses covering the plurality of pixel regions, respectively.

17. The camera module of claim 16, wherein the diameter of each micro lens is larger than the corresponding size of the respective pixel region.

18. The camera module of claim 16, wherein the micro-lens array is made of photoresist material.

19. The camera module of claim 11, further comprising a micro-lens array overlaying a surface of the color filter layer that is farthest away from the cover glass.

20. The camera module of claim 11, wherein the color filter layer comprises a plurality of red color filters, a plurality of green color filters, and a plurality of blue color filters.
